(19) United States
(12) Patent Application Publication
(10) Pub. No.: US 2017/0179362 A1
(43) Pub. Date: Jun. 22, 2017

(54) THERMOELECTRIC CONVERSION ELEMENT, n-TYPE THERMOELECTRIC CONVERSION LAYER, AND COMPOSITION FOR FORMING n-TYPE THERMOELECTRIC CONVERSION LAYER

(71) Applicant: FUJIFILM Corporation, Tokyo (JP)

(72) Inventors: Yuzo NAGATA, Ashigara-kami-gun (JP); Hiroki SUGIURA, Ashigara-kami-gun (JP); Naoyuki HAYASHI, Ashigara-kami-gun (JP); Kimiatsu NOMURA, Ashigara-kami-gun (JP)

(73) Assignee: FUJIFILM Corporation, Tokyo (JP)

(21) Appl. No.: 15/452,233

(22) Filed: Mar. 7, 2017

Related U.S. Application Data
(63) Continuation of application No. PCT/JP2015/074860, filed on Sep. 1, 2015.

(30) Foreign Application Priority Data
Sep. 8, 2014 (JP) 2014-182085
Mar. 11, 2015 (JP) 2015-048252

(51) Int. Cl. H01L 35/22; H01L 35/34; H01L 35/24; C08K 7/24; H01L 35/26

(52) U.S. Cl. CPC H01L 35/22; C08K 7/24; H01L 35/26; H01L 35/24; H01L 35/34; C08K 2201/001; C08K 2201/011

(57) ABSTRACT

The present invention provides an n-type thermoelectric conversion layer, which has excellent electric conductivity and thermoelectromotive force and is inhibited from experiencing a change of the thermoelectromotive force even in a high-temperature environment, a thermoelectric conversion element having the n-type thermoelectric conversion layer, and a composition for forming an n-type thermoelectric conversion layer. A thermoelectric conversion element of the present invention has an n-type thermoelectric conversion layer and a p-type thermoelectric conversion layer electrically connected to the n-type thermoelectric conversion layer, in which the n-type thermoelectric conversion layer contains carbon nanotubes and a compound containing a repeating unit represented by Formula (1).

L₁-Xₙ Formula (1)

In Formula (1), L₁ represents a divalent hydrocarbon group. n represents an integer of equal to or greater than 2.

X represents —O—, —CH(OH)—, —S—, —OC(═O)O—, —C(═O)—, —OC(═O)—, or a divalent group containing an amide group.

### CROSS-REFERENCE TO RELATED APPLICATIONS

This application is a Continuation of PCT International Application No. PCT/JP2015/074860 filed on Sep. 1, 2015, which claims priority under 35 U.S.C. §119(a) to Japanese Patent Application No. 2014-182085 filed on Sep. 8, 2014 and Japanese Patent Application No. 2015-048252 filed on Mar. 11, 2015. Each of the above applications is hereby expressly incorporated by reference, in its entirety, into the present application.

### BACKGROUND OF THE INVENTION

1. Field of the Invention

The present invention relates to a thermoelectric conversion element, an n-type thermoelectric conversion layer, and a composition for forming an n-type thermoelectric conversion layer.

2. Description of the Related Art

Thermoelectric conversion materials that enable the interconversion of thermal energy and electric energy are used in power generating elements generating electric power from heat or thermoelectric conversion elements such as a Peltier element. Thermoelectric conversion elements can convert thermal energy directly into electric power, do not require a moving portion, and are used in, for example, wrist watches operating by body temperature, power supplies for backwoods, and aerospace power supplies.

As one of the evaluation indices of the thermoelectric conversion performance of thermoelectric conversion elements, there is a dimensionless figure of merit ZT (hereinafter, simply referred to as a figure of merit ZT in some cases). The figure of merit ZT is represented by the following Equation (A). For improving the thermoelectric conversion performance, it is important to improve a thermoelectromotive force S per absolute temperature of 1 K (hereinafter, referred to as a thermoelectromotive force in some cases) and an electric conductivity σ and to reduce a thermal conductivity κ.

Figure of merit ZT=S²·σ·T/κ (A)

In Equation (A), S (V/K) is a thermoelectromotive force (Seebeck coefficient) per absolute temperature of 1 K, σ (S/m) is an electric conductivity, κ (W/mK) is a thermal conductivity, and T (K) is an absolute temperature.

As one of the typical constitutions of thermoelectric conversion elements, for example, there is a constitution in which a p-type thermoelectric conversion material and an n-type thermoelectric conversion material are electrically connected to each other. Generally, as the n-type thermoelectric conversion material, an inorganic material such as nickel is known. Unfortunately, the inorganic material is expensive, contains toxic substances, and needs to undergo a complicated process for being made into a thermoelectric conversion element.

Therefore, in recent years, techniques using carbon materials represented by carbon nanotubes (hereinafter, referred to as “CNT” as well) have been suggested. For example, Scientific Reports 2013, 3, 3344-1-7 discloses an aspect in which an n-type thermoelectric conversion material is provided by adding a dopant to a carbon material.

### SUMMARY OF THE INVENTION

Meanwhile, in recent years, in order to improve the performance of instruments using thermoelectric conversion elements, further improvement of the thermoelectric conversion performance of the thermoelectric conversion elements has been required.

Usually, at the time of preparing a CNT-containing thermoelectric conversion layer, a composition in which CNT is dispersed is generally used in many cases.

Therefore, the inventors of the present invention first conducted investigation regarding the characteristics of a composition containing CNT and a dopant (triphenylphosphine) described in Scientific Reports 2013, 3, 3344-1-7. As a result, they found that the dispersibility of CNT in the composition is not necessarily sufficient.

The inventors also conducted investigation regarding the performance of the n-type thermoelectric conversion layer formed using the composition exhibiting poor CNT dispersibility. As a result, they found that the electric conductivity or the thermoelectromotive force of the n-type thermoelectric conversion layer does not satisfy the currently required level and needs to be further improved.

In addition, they found that, in a case where the n-type thermoelectric conversion layer, to which a dopant known in the related art is added, is left to stand in a heating environment, unfortunately, the thermoelectromotive force thereof greatly changes. That is, they found that heat stability thereof is poor.

The present invention has been made in consideration of the above circumstances, and an object is to provide an n-type thermoelectric conversion layer, which has excellent electric conductivity and thermoelectromotive force and is inhibited from experiencing a change of the thermoelectromotive force even in a high-temperature environment, and a thermoelectric conversion element having the n-type thermoelectric conversion layer.

Another object of the present invention is to provide a composition for forming an n-type thermoelectric conversion layer that is excellent in dispersion stability of carbon nanotubes and makes it possible to form an n-type thermoelectric conversion layer which has excellent electric conductivity and thermoelectromotive force and is inhibited from experiencing a change of the thermoelectromotive force even in a high-temperature environment.

Regarding the aforementioned objects, the inventors of the present invention conducted intensive investigation. As a result, they found that the use of a compound having a predetermined structure brings about desired effects.

More specifically, they found that the aforementioned objects can be achieved by the following constitutions.

(1) A thermoelectric conversion element comprising an n-type thermoelectric conversion layer and a p-type thermoelectric conversion layer electrically connected to the n-type thermoelectric conversion layer, in which the n-type thermoelectric conversion layer contains carbon nanotubes and a compound containing a repeating unit represented by Formula (1) which will be described later.

(2) The thermoelectric conversion element according to (1), in which the compound has a monovalent hydrocarbon group having 10 or more carbon atoms.

(3) The thermoelectric conversion element according to (1) or (2), in which X in Formula (1) is —O—.

(4) The thermoelectric conversion element according to (1) or (2), in which the compound contains a compound represented by Formula (3) which will be described later.

(5) The thermoelectric conversion element according to (4), in which X in Formula (3) is —O—.

(6) The thermoelectric conversion element according to any one of (1) to (5), in which n is 10 to 120.

(7) The thermoelectric conversion element according to (2), in which the monovalent hydrocarbon group is a monovalent aromatic hydrocarbon group.

(8) An n-type thermoelectric conversion layer comprising carbon nanotubes and a compound containing a repeating unit represented by Formula (1) which will be described later.

(9) The n-type thermoelectric conversion layer according to (8), in which the compound has a monovalent hydrocarbon group having 10 or more carbon atoms.

(10) The n-type thermoelectric conversion layer according to (8) or (9), in which the compound contains a compound represented by Formula (3) which will be described later.

(11) The n-type thermoelectric conversion layer according to any one of (8) to (10), in which n is 10 to 120.

(12) The n-type thermoelectric conversion layer according to (9), in which the monovalent hydrocarbon group is a monovalent aromatic hydrocarbon group.

(13) A composition for forming an n-type thermoelectric conversion layer, comprising carbon nanotubes and a compound containing a repeating unit represented by Formula (1) which will be described later.

(14) The composition for Ruining an n-type thermoelectric conversion layer according to (13), in which the compound has a monovalent hydrocarbon group having 10 or more carbon atoms.

(15) The composition for forming an n-type thermoelectric conversion layer according to (13) or (14), in which the compound contains a compound represented by Formula (3) which will be described later.

(16) The composition for forming an n-type thermoelectric conversion layer according to any one of (13) to (15), in which n is 10 to 120.

(17) The composition for forming an n-type thermoelectric conversion layer according to (14), in which the monovalent hydrocarbon group is a monovalent aromatic hydrocarbon group.

(18) The composition for forming an n-type thermoelectric conversion layer according to any one of (13) to (17), further comprising water or an alcohol-based solvent having a C log P value of equal to or less than 3.0.

(19) A method for manufacturing a thermoelectric conversion element, comprising a step of performing a washing treatment on an element including an n-type thermoelectric conversion layer, which contains carbon nanotubes and a compound containing a repeating unit represented by Formula (1) which will be described later, and a p-type thermoelectric conversion layer, which is electrically connected to the n-type thermoelectric conversion layer and contains carbon nanotubes and a dispersant, by using a solvent which dissolves the dispersant without dissolving the compound containing a repeating unit represented by Formula (1).

According to the present invention, it is possible to provide an n-type thermoelectric conversion layer, which has excellent electric conductivity and thermoelectromotive force and is inhibited from experiencing a change of the thermoelectromotive force even in a high-temperature environment, and a thermoelectric conversion element having the n-type thermoelectric conversion layer.

Furthermore, according to the present invention, it is possible to provide a composition for forming an n-type thermoelectric conversion layer that is excellent in dispersion stability of carbon nanotubes and makes it possible to form an n-type thermoelectric conversion layer which has excellent electric conductivity and thermoelectromotive force and is inhibited from experiencing a change of the thermoelectromotive force even in a high-temperature environment.

### BRIEF DESCRIPTION OF THE DRAWINGS

FIG. 1 is a cross-sectional view schematically showing an example of a thermoelectric conversion element of the present invention. The arrow in FIG. 1 shows the direction of a temperature difference made at the time of using the element.

FIG. 2 is a cross-sectional view schematically showing an example of the thermoelectric conversion element of the present invention.

FIG. 3 is a cross-sectional view schematically showing an example of the thermoelectric conversion element of the present invention. The arrow in FIG. 3 shows the direction of a temperature difference made at the time of using the element.

FIG. 4 is a cross-sectional view schematically showing a thermoelectric conversion element prepared in examples.

### DESCRIPTION OF THE PREFERRED EMBODIMENTS

Hereinafter, suitable aspects of the thermoelectric conversion element and the like of the present invention will be described. In the present specification, a range of numerical values described using “to” means a range that includes numerical values listed before and after “to” as a lower limit and an upper limit.

One of the characteristics of the thermoelectric conversion element of the present invention is that it uses a compound having a predetermined structure, for example. Details of the reason why the use of such a compound brings about desired effects are unclear but are assumed to be as below.

The compound used in the present invention (compound containing a repeating unit represented by Formula (1)) is presumed to function as a dispersant for CNT and as a carrier supply source in a thermoelectric conversion layer. This compound readily interacts with the surface of CNT and hence exhibits relatively high CNT dispersibility. Consequently, CNT in a bundle form can be unraveled and dispersed, the performance intrinsic to CNT is easily demonstrated, and excellent electric conductivity and thermoelectromotive force are exhibited. Furthermore, this compound contains an oxygen atom, a sulfur atom, and the like. Presumably, electrons derived from a lone electron pair in such a heteroatom may be donated onto CNT, and the donation may make a contribution to the inhibition of a decrease in the thermoelectromotive force in a high-temperature environment.

Hereinafter, a composition used for forming a predetermined n-type thermoelectric conversion layer (composition for forming an n-type thermoelectric conversion layer) will be specifically described first, and then a thermoelectric conversion element having an n-type thermoelectric conversion layer formed using the composition will be specifically described.

<Composition for Forming n-Type Thermoelectric Conversion Layer>

The composition for forming an n-type thermoelectric conversion layer (hereinafter, simply referred to as a “composition” as well) contains at least carbon nanotubes and a compound containing a repeating unit represented by Formula (1).

Hereinafter, each component contained in the composition will be specifically described.

(Carbon Nanotubes)

As the carbon nanotubes (CNT) used in the present invention, there are single-layer CNT formed of one sheet of carbon film (graphene sheet) wound in the form of a cylinder, double-layered CNT formed of two graphene sheets wound in the form of concentric circles, and multilayered CNT formed of plural graphene sheets wound in the form of concentric circles. In the present invention, one kind of each of the single-layer CNT, double-layered CNT, and multilayered CNT may be used singly, or two or more kinds thereof may be used in combination. Particularly, the single-layer CNT having excellent properties in terms of electric conductivity and semiconductor characteristics and the double-layered CNT are preferably used, and the single-layer CNT is more preferably used.

The single-layer CNT used in the present invention may be semiconductive or metallic, and both of semiconductive CNT and metallic CNT may be used in combination. Furthermore, CNT may contain a metal or the like, and CNT containing a fullerene molecule and the like (particularly, CNT containing fullerene is called a pivot) may be used.

CNT can be manufactured by an arc discharge method, a chemical vapor deposition method (hereinafter, referred to as a CVD method), a laser•ablation method, and the like. CNT used in the present invention may be obtained by any method, but it is preferable to use CNT obtained by the arc discharge method and the CVD method.

At the time of manufacturing CNT, fullerene or graphite and amorphous carbon are also generated as by-products in some cases. In order to remove these by-products, CNT may be purified. The CNT purification method is not particularly limited, and examples thereof include methods such as washing, centrifugation, filtration, oxidation, and chromatography. In addition, an acid treatment using nitric acid, sulfuric acid, and the like and an ultrasonic treatment are also effective for removing impurities. Furthermore, from the viewpoint of improving purity, it is more preferable to separate and remove impurities by using a filter.

CNT obtained after purification may be used as it is. Furthermore, because of being generated in the form of strings in general, CNT may be used after being cut in a desired length according to the purpose. By an acid treatment using nitric acid, sulfuric acid, or the like, an ultrasonic treatment, a freezing and pulverizing method, and the like, CNT can be cut in the form of short fiber. From the viewpoint of improving purity, it is also preferable to collectively separate CNT by using a filter.

In the present invention, not only cut CNT but also CNT prepared in the form of short fiber can also be used.

An average length of CNT is not particularly limited. From the viewpoint of ease of manufacturing, film formability, electric conductivity, and the like, the average length is preferably 0.01 to 1,000 μm, and more preferably 0.1 to 100 μm. An average diameter of CNT is not particularly limited. From the viewpoint of durability, transparency, film formability, electric conductivity, and the like, the average diameter is preferably equal to or greater than 0.4 nm and equal to or less than 100 nm (more preferably equal to or less than 50 nm and even more preferably equal to or less than 15 nm).

In view of a thermoelectric conversion performance, a content of carbon nanotubes in the composition is, with respect to total solid contents in the composition, preferably 5% to 80% by mass, more preferably 5% to 70% by mass, and particularly preferably 5% to 50% by mass.

One kind of carbon nanotubes may be used singly, or two or more kinds thereof may be used in combination.

The aforementioned solid contents meant components forming the thermoelectric conversion layer and do not include a solvent.

(Compound Containing Repeating Unit Represented by Formula (1))

The composition contains a compound containing a repeating unit represented by Formula (1). As described above, the compound is considered to function as a dispersant for CNT as well.

L₁-Xₙ Formula (1)

In Formula (1), L₁ represents a divalent hydrocarbon group. A plurality of L₁'s may be the same as or different from each other.

The number of carbon atoms in the hydrocarbon group is not particularly limited, but is preferably 1 to 10, more preferably 2 to 6, and even more preferably 2 to 4.

The hydrocarbon group may be a saturated hydrocarbon group or an unsaturated hydrocarbon group. Furthermore, the hydrocarbon group may be a non-aromatic hydrocarbon group or an aromatic hydrocarbon group. More specifically, examples thereof include an alkylene group, an alkenylene group, an alkynylene group, and an arylene group. Among these, in view of further improving CNT dispersibility and/or further improving the characteristics (electric conductivity, thermoelectromotive force, and heat stability) of the n-type thermoelectric conversion layer (hereinafter, simply described as “further improving effects of the present invention”), an alkylene group is preferable.

The alkylene group may be linear, branched, or cyclic. Examples of the alkylene group include a methylene group, an ethylene group, a propylene group, and the like.

In Formula (1), X represents —O—, —CH(OH)—, —S—, —OC(═O)O—, —C(═O)—, —OC(═O)—, or a divalent group containing an amide group. Among these, in view of further improving effects of the present invention, —O—, —CH(OH)—, or a group represented by Formula (2) which will be described later is preferable, and —O— is more preferable.

The divalent group containing an amide group is a group which contains an amide group and has two direct bonds, and examples thereof preferably include —NRCO— (R represents a hydrogen atom or a monovalent organic group (preferably an alkyl group)) and a group represented by Formula (2).

A plurality of X's may be the same as or different from each other.

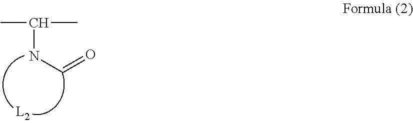

In Formula (2), L₂ represents a divalent hydrocarbon group. The divalent hydrocarbon group has the same definition as the divalent hydrocarbon group represented by L₁, and a suitable range thereof is also the same.

In Formula (1), n represents the number of repeating units that is an integer of equal to or greater than 2. That is, the present compound is also a polymer having repeating units.

In view of further improving effects of the present invention, n is preferably 2 to 200, more preferably 10 to 120, even more preferably greater than 10 and equal to or less than 100, particularly preferably 15 to 50, and most preferably greater than 20 and equal to or less than 40.

Examples of the compound having a repeating unit represented by Formula (1) in which L₁ is a methylene group and X is —O— include polyalkylene oxide.

Examples of the compound having a repeating unit represented by Formula (1) in which L₁ is a methylene group and X is —CH(OH)— include polyvinyl alcohol.

Examples of the compound having a repeating unit represented by Formula (1) in which L₁ is a methylene group and X is a group represented by Formula (2) include polyvinyl pyrrolidone.

The compound containing a repeating unit represented by Formula (1) may contain repeating units other than the repeating unit represented by Formula (1).

Furthermore, the compound may contain two or more kinds of repeating unit represented by Formula (1).

(Suitable Aspect (1))

As one of the suitable aspects of the compound containing a repeating unit represented by Formula (1), an aspect is exemplified in which the compound contains a monovalent hydrocarbon group having 5 or more carbon atoms. If the compound contains such a monovalent hydrocarbon group, the monovalent hydrocarbon group easily functions as a so-called hydrophobic moiety, and the repeating unit represented by Formula (1) easily functions as a hydrophilic moiety. As a result, the CNT dispersibility is further improved, and the characteristics of the formed n-type thermoelectric conversion layer are further improved.

A binding position of the monovalent hydrocarbon group is not particularly limited, but it is preferable that the monovalent hydrocarbon group is disposed on at least one of the main chain terminals of the compound (polymer).

The number of carbon atoms contained in the monovalent hydrocarbon group is equal to or greater than 5. In view of further improving effects of the present invention, the number of carbon atoms is preferably equal to or greater than 10, and more preferably equal to or greater than 15. An upper limit thereof is not particularly limited, but in view of CNT dispersibility and synthesis, the upper limit is preferably equal to or less than 30.

The monovalent hydrocarbon group may be a monovalent aliphatic hydrocarbon group, a monovalent aromatic hydrocarbon group, or a group as a combination of these.

The monovalent aliphatic hydrocarbon group may be linear, branched, or cyclic, or may be a combination of these. Specific examples thereof include an alkyl group, an alkenyl group, an alkynyl group, and the like.

The monovalent aromatic hydrocarbon group (aryl group) may have a monocyclic structure or a polycyclic structure (so-called fused polycyclic aromatic hydrocarbon group). In a case where the monovalent aromatic hydrocarbon group has a polycyclic structure, the number of rings thereof is preferably equal to or greater than 3, and more preferably equal to or greater than 4. Specific examples thereof include a phenyl group, a naphthyl group, an anthryl group, a pyrenyl group, a phenanthrenyl group, a biphenyl group, a fluorenyl group, and the like.

As the most suitable aspect of the compound, a compound represented by Formula (3) is exemplified.

R₁-L₃L₁-XₙR₂ Formula (3)

In Formula (3), L₁, X, and n have the same definition as L₁, X, and n in Formula (1) respectively.

In Formula (3), R₁ represents a monovalent hydrocarbon group having 5 or more (preferably 10 or more) carbon atoms. The definition of the monovalent hydrocarbon group is the same as described above.

In Formula (3), L₃ represents a single bond or a divalent linking group. Examples of the divalent linking group include a divalent hydrocarbon group (the divalent hydrocarbon group may be a divalent saturated hydrocarbon group or a divalent aromatic hydrocarbon group. The divalent saturated hydrocarbon group may be linear, branched, or cyclic and preferably has 1 to 20 carbon atoms. Examples thereof include an alkylene group. The divalent aromatic hydrocarbon group preferably has 5 to 20 carbon atoms, and examples thereof include a phenylene group. The divalent aromatic hydrocarbon group may also be an alkenylene group or an alkynylene group.), a divalent heterocyclic group, —O—, —S—, —SO₂—, —NR_{L}—, —CO—, —COO—, —CONR_{L}—, —SO₃—, —SO₂NR_{L}—, a group obtained by combining two or more kinds of these (for example, an alkyleneoxy group, an alkyleneoxycarbonyl group, or an alkylenecarbonyloxy group), and the like. Among these, an alkylene group, —O—, —COO—, or a combination of these is preferable.

In Formula (3), R₂ represents a hydrogen atom or a monovalent organic group. The monovalent organic group is not particularly limited, and examples thereof include an alkyl group, a cycloalkyl group, an aryl group, an alkylcarbonyl group, a cycloalkylcarbonyl group, an arylcarbonyl group, an alkyloxycarbonyl group, a cycloalkyloxycarbonyl group, an aryloxycarbonyl group, an alkylaminocarbonyl group, a cycloalkylaminocarbonyl group, an arylaminocarbonyl group, and the like. These groups may further have a substituent.

A method for synthesizing the compound containing a repeating unit represented by Formula (1) is not particularly limited, and the compound can be synthesized by a known method. Furthermore, commercially available products can be used.

Examples of the compound include a polyethylene glycol-type higher alcohol ethylene oxide adduct, an ethylene oxide adduct of phenol or naphthol, a fatty acid ethylene oxide adduct, a polyhydric alcohol fatty acid ester ethylene oxide adduct, a higher alkylamine ethylene oxide adduct, a fatty acid amide ethylene oxide adduct, an ethylene oxide adduct of fat and oil, a polypropylene glycol ethylene oxide adduct, a dimethyl siloxane-ethylene oxide block copolymer, a dimethylsiloxane-(propylene oxide-ethylene oxide) block copolymer, a fatty acid ester of polyhydric alcohol-type glycerol, a fatty acid ester of pentaerythritol, a fatty acid ester of sorbitol and sorbitan, a fatty acid ester of sucrose, an alkyl ether of polyhydric alcohol, a fatty acid amide of alkanolamines, and the like. Furthermore, it is also possible to use oxyethylene adducts based on acetylene glycol and acetylene alcohol and surfactants based on fluorine, silicone, and the like.

(Suitable Aspect (2))

As one of the suitable aspects of the compound containing a repeating unit represented by Formula (1), a compound is exemplified which contains a repeating unit represented by the following Formula (1A) and a repeating unit represented by the following Formula (1B).

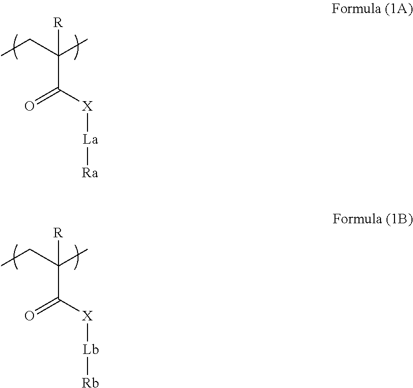

In Formula (1A), Ra represents an aromatic group, an alicyclic group, an alkyl group, a hydroxyl group, a thiol group, an amino group, an ammonium group, or a carboxy group. La represents a single bond or a divalent linking group. R represents a hydrogen atom or an alkyl group having 1 to 4 carbon atoms. X represents an oxygen atom or —NH—.

In Formula (1B), Rb represents a group containing a repeating unit represented by Formula (1). Lb represents a single bond or a divalent linking group. R has the same definition as R in Formula (1A). X represents an oxygen atom or —NH—.

Ra in Formula (1A) corresponds to a group adsorbed onto carbon nanotubes. Ra is preferably an aromatic group or a hydroxyl group.

The ring constituting the aromatic group as Ra may be an aromatic hydrocarbon ring or an aromatic heterocyclic ring. Examples of the heteroatom of the heterocyclic ring include a nitrogen atom, a sulfur atom, an oxygen atom, and a selenium atom. The ring may be monocyclic ring or a fused ring, and is preferably a 5-membered ring, a 6-membered ring, or a fused ring of these, and more preferably a 6-membered ring or a fused ring thereof. Specific examples thereof include a benzene ring, a naphthalene ring, an anthracene ring, a pyrene ring, a chrysene ring, a tetracene ring, a tetraphene ring, a triphenylene ring, an indole ring, an isoquinoline ring, a quinoline ring, a chromene ring, an acridine ring, a xanthene ring, a carbazole ring, a porphyrin ring, a chlorine ring, and a corrin ring. The ring constituting the aromatic group as Ra is preferably an aromatic hydrocarbon ring, more preferably a benzene ring or a fused ring of benzene rings, and even more preferably a benzene ring or a fused ring in which 2 to 4 benzene rings are fused with each other.

The alicyclic compound constituting the alicyclic group as Ra may contain a heteroatom, and examples of the heteroatom include a nitrogen atom, a sulfur atom, an oxygen atom, and a selenium atom. The alicyclic compound may be a monocyclic ring or a fused ring, and is preferably a 5-membered ring, a 6-membered ring, or a fused ring of these and more preferably a 6-membered ring or a fused ring thereof. Furthermore, the alicyclic compound may be a saturated ring or an unsaturated ring, and specific examples thereof include a cyclohexane ring, a cyclopropane ring, an adamantyl ring, and a tetrahydronaphthalene ring. The alicyclic compound is preferably a hydrocarbon ring which is a 6-membered hydrocarbon ring or a fused ring thereof.

The alkyl group as Ra may be linear, branched, or cyclic, and is preferably a linear alkyl group. The number of carbon atoms of alkyl group is preferably 1 to 30, and more preferably 5 to 20.

The amino group as Ra includes an alkylamino group and an arylamino group, and specific examples thereof include a dimethylamino group, a diethylamino group, a dibutylamino group, a dipropylamino group, a methylamino group, an ethylamino group, a butylamino group, a propylamino group, and an amino group. Among these, an alkylamino group is preferable. The number of carbon atoms of each alkyl group of the alkylamino group is preferably has 1 to 7, and more preferably 1 to 4.

The ammonium group as Ra includes an alkylammonium group and an arylammonium group. Specific examples thereof include a trimethylammonium group, a triethylammonium group, a tripropylammonium group, and a tributylammonium group. Among these, an alkylammonium group is preferable. The number of carbon atoms of each alkyl group of the alkylammonium group is preferably 1 to 7, and more preferably 1 to 4.

Examples of the thiol group as Ra include a thioalkyl group.

Each group as Ra may further have a substituent.

In Formula (1A), examples of the divalent linking group as La include an alkylene group, —O—, —CO—, —COO—, —CONH—, —NR¹¹—, —N⁺R¹¹R¹²—, —S—, —S(═O)—, and a divalent group obtained by combining these. R¹¹ and R¹² each independently represent a hydrogen atom or an alkyl group, and each alkyl group preferably has 1 or 2 carbon atoms. The alkylene group may have a substituent, and examples of the substituent include a hydroxyl group, a thiol group, an ether group, an ester group, and an amide group. The number of carbon atoms of the alkylene group is preferably 1 to 4, and more preferably 1 to 3.

La is preferably an alkylene group, a divalent obtained by combining an alkylene group, —O—, and —CO—, or a divalent group obtained by combining an alkylene group, —N⁺R¹¹R¹²—, and —CO—. In a case where a plurality of groups is combined, it is more preferable that La is bonded to X through an alkylene group and to Rb through —CO—.

The alkyl group as R may be linear, branched, or cyclic, and is preferably a linear alkyl group. The alkyl group may be substituted, and as the substituent, a halogen atom, an oxygen atom, or a sulfur atom is preferable. The number of carbon atoms of the alkyl group is preferably 1 to 3, and more preferably 1 or 2.

R is preferably an alkyl group having 1 or 2 carbon atoms, and more preferably a methyl group.

Rb in Formula (1B) is a group containing a repeating unit represented by Formula (1).

The repeating unit represented by Formula (1) is as described above.

In view of further improving effects of the present invention, Rb is preferably a group represented by Formula (1C).

L₁-XₙRc Formula (1C)

L₁, X, and n have the same definition as described above, and a suitable range thereof is the same as described above.

Rc represents a hydrogen atom or a hydrocarbon group, and the hydrocarbon group is preferably an alkyl group (preferably having 1 to 5 carbon atoms).

Examples of the divalent linking group as Lb include an alkylene group, —O—, —CO—, —COO—, —CONH—, —NR¹¹—, —N⁺R¹¹R¹²—, —S—, —S(═O)—, and a divalent group obtained by combining these. R¹¹ and R¹² each independently represent a hydrogen atom or an alkyl group, and each alkyl group preferably has 1 or 2 carbon atoms. The alkylene group may have a substituent, and examples of the substituent include a hydroxyl group, a halogen atom, an alkyl group, an alkoxy group, an amino group, an ammonium group, and an ester group. The number of carbon atoms of the alkylene group is preferably 1 to 7. The number of carbon atoms of Lb is preferably 1 to 20, and more preferably 1 to 10.

Lb is preferably a divalent group obtained by combining an alkylene group, —O—, —CO—, and —S—. In this case, Lb is preferably bonded to X through an alkylene group and to Rb through —S—.

R in Formula (1B) has the same definition as R in Formula (1A), and a preferred range thereof is also the same.

X in Formula (1B) represents an oxygen atom or —NH—, and is preferably an oxygen atom.

The dispersant of the present invention may contain a repeating unit other than the repeating units (1A) and (1B), but is preferably a copolymer consisting of the repeating units (1A) and (1B).

In the copolymer containing the repeating units (1A) and (1B), a compositional ratio between the repeating units (1A) and (1B) denoted by repeating unit (1A):repeating unit (1B) is preferably 20 to 90:80 to 10 and more preferably 40 to 80:60 to 20, based on moles.

A weight-average molecular weight of the compound containing the repeating unit represented by Formula (1A) and the repeating unit represented by Formula (1B) is preferably 1,000 to 800,000, and more preferably 10,000 to 300,000. The weight-average molecular weight can be measured by gel permeation chromatography (GPC). For example, the weight-average molecular weight can be measured using a high-performance GPC device (for example, HLC-8220GPC (manufactured by Tosoh Corporation)) by dissolving the dispersant in tetrahydrofuran (THF) and calculated in terms of polystyrene. The conditions of GPC are as below.

Column: TSK-GEL SuperH manufactured by Tosoh Corporation

Column temperature: 40° C.

Flow rate: 1 mL/min

Eluent: THF

A content of the compound having a repeating unit represented by Formula (1) in the composition is not particularly limited. In view of further improving effects of the present invention, the content is preferably 10 to 1,000 parts by mass and more preferably 50 to 400 parts by mass with respect to 100 parts by mass of the carbon nanotubes.

One kind of compound containing a repeating unit represented by Formula (1) may be used singly, or two or more kinds thereof may be used in combination.

Examples of the compound containing the repeating unit represented by Formula (1) include the following compounds.

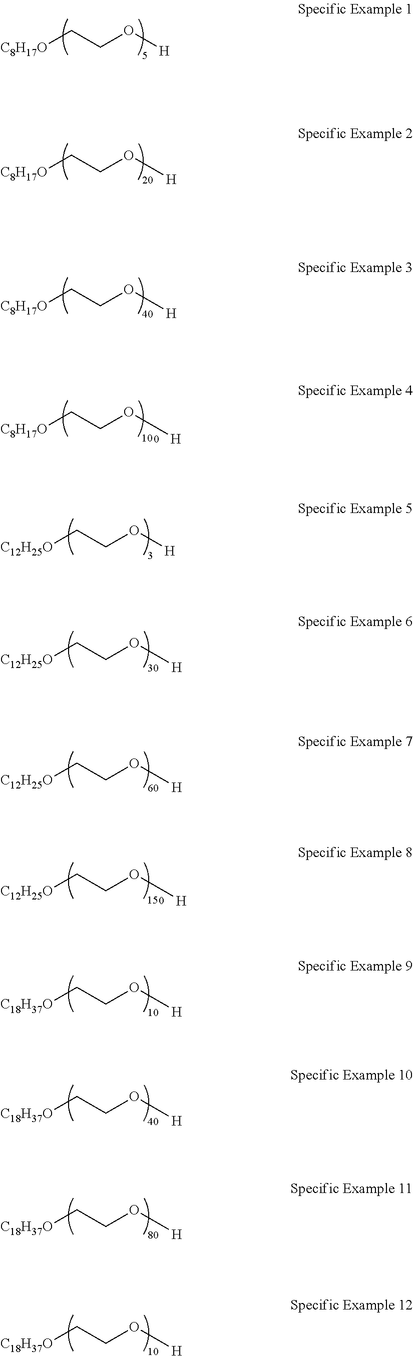

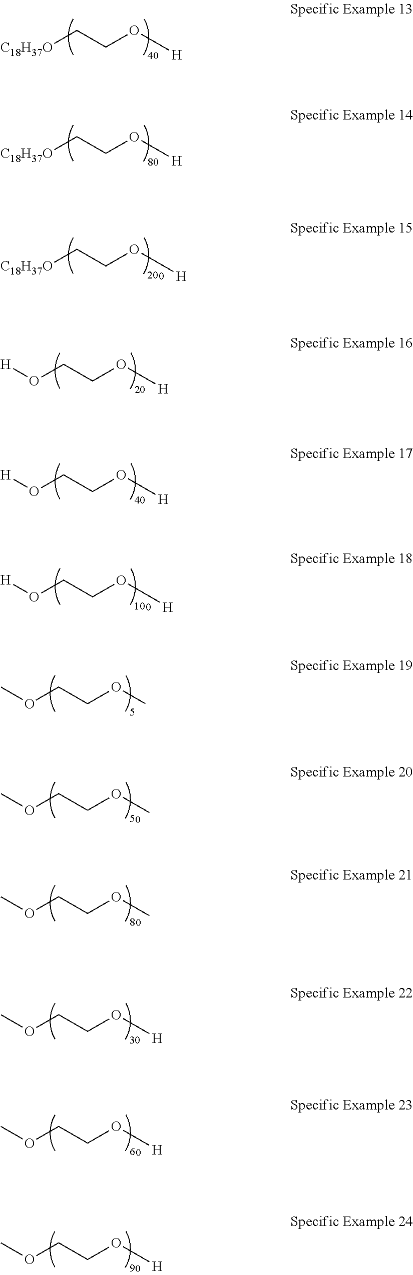

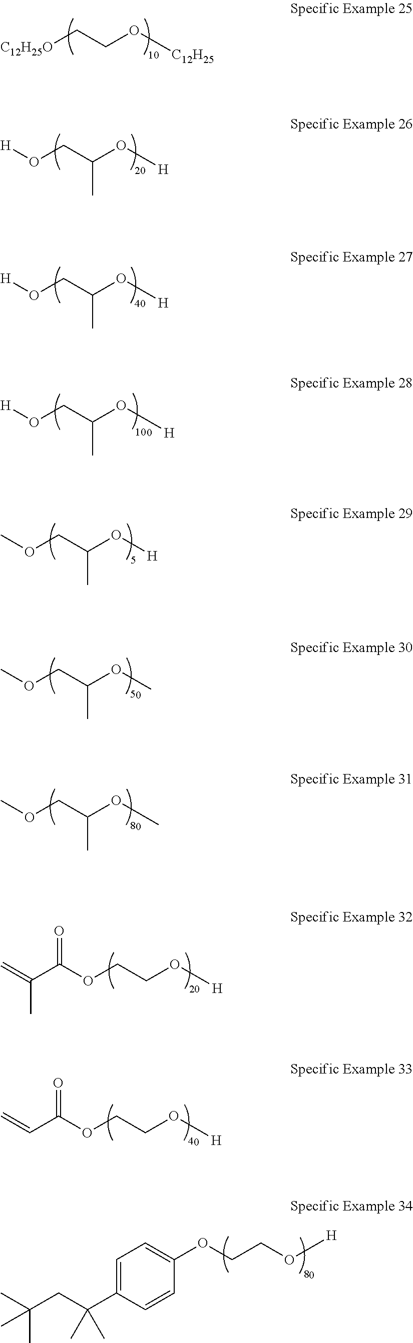

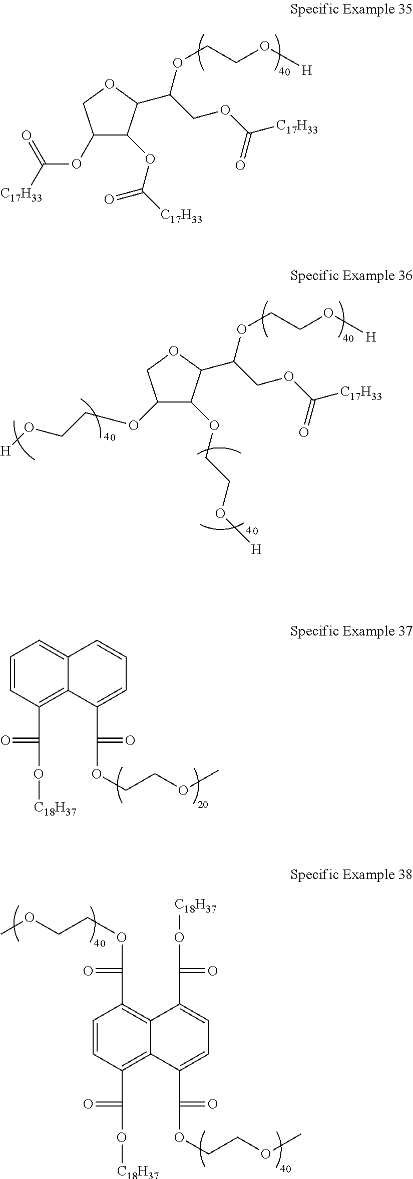

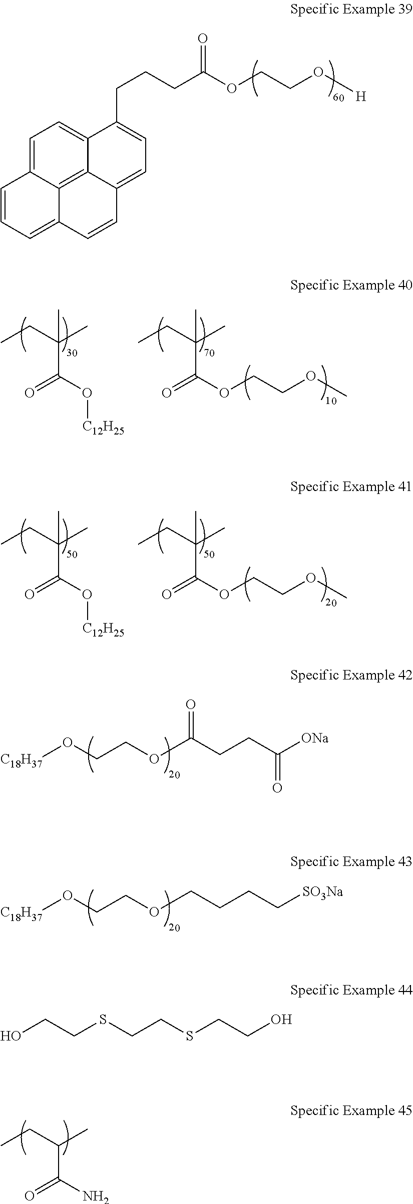

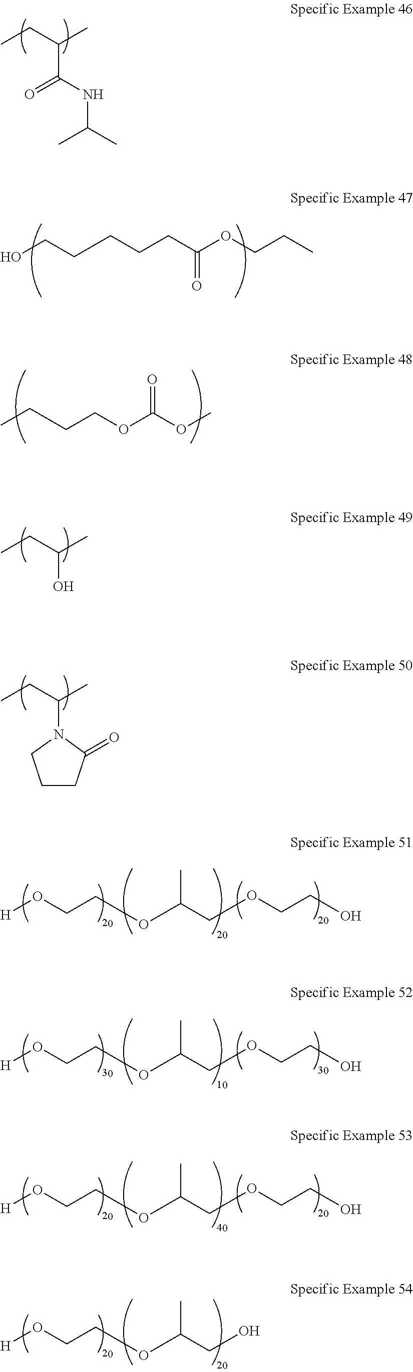

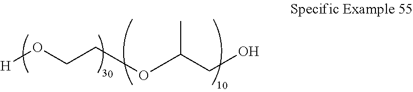

(Other Optional Components)

The composition of the present invention may contain components (a dispersion medium, polymer compounds other than the aforementioned compound (hereinafter, referred to as other polymer compounds), a surfactant, an antioxidant, a lightfast stabilizer, a heat-resistant stabilizer, a plasticizer, and the like) other than the aforementioned CNT and the compound containing the repeating unit represented by Formula (1).

The dispersion medium (solvent) is not limited as long as it can disperse CNT, and water, an organic solvent, and a mixed solvent of these can be used. Examples of the organic solvent include an alcohol-based solvent, an aliphatic halogen-based solvent such as chloroform, an aprotic polar solvent such as dimethylformamide (DMF), N-methyl-2-pyrrolidone (NMP), or dimethylsulfoxide (DMSO), an aromatic solvent such as chlorobenzene, dichlorobenzene, benzene, toluene, xylene, mesitylene, tetralin, tetramethylbenzene, or pyridine, a ketone-based solvent such as cyclohexanone, acetone, or methyl ethyl ketone, an ether-based solvent such as diethylehter, THF, t-butylmethylether, dimethoxyethane, or diglyme, and the like.

One kind of dispersion medium can be used singly, or two or more kinds thereof can be used in combination.

It is preferable that the dispersion medium has undergone deaeration. A dissolved oxygen concentration in the dispersion medium is preferably equal to or lower than 10 ppm. Examples of the deaeration method include a method of irradiating the dispersion medium with ultrasonic waves under reduced pressure, a method of performing bubbling using an inert gas such as argon, and the like.

In a case where a solvent other than water is used as the dispersion medium, it is preferable to perform deaeration in advance. A moisture amount in the dispersion medium is preferably equal to or less than 1,000 ppm, and more preferably equal to or less than 100 ppm. As the deaeration method for the dispersion medium, it is possible to use known methods such as a method using a molecular sieve and distillation.

A content of the dispersion medium in the composition is, with respect to a total amount of the composition, preferably 25% to 99.99% by mass, more preferably 30% to 99.95% by mass, and even more preferably 30% to 99.9% by mass.

As the dispersion medium, water and an alcohol-based solvent which has a C log P value of equal to or less than 3.0 are suitably exemplified, because these are excellent in the dispersibility of carbon nanotubes and further improve the characteristics (electric conductivity and thermoelectromotive force) of the n-type thermoelectric conversion layer. The C log P value will be specifically described later.

The alcohol-based solvent means a solvent containing a —OH group (hydroxy group).

The C log P value of the alcohol-based solvent is equal to or less than 3.0. The C log P value is preferably equal to or less than 1.0, because then the CNT dispersibility is further improved, and the characteristics of the n-type thermoelectric conversion element are further improved. A lower limit of thereof is not particularly limited. In view of the aforementioned effects, the lower limit is preferably equal to or greater than −3.0, more preferably equal to or greater than −2.0, and even more preferably equal to or greater than −1.0.

A log P value is a common logarithm of a partition coefficient P. It is a physical property value showing how a certain compound is partitioned in equilibrium of two phase system consisting of oil (herein, n-octanol) and water by using a quantitative numerical value. The greater the log P value, the more the compound is hydrophobic, and the smaller the log P value, the more the compound is hydrophilic. Therefore, the log P value can be used as an index showing hydrophilicity and hydrophobicity of a compound.

log P=log(Coil/Cwater)

Coil=molar concentration in oil phase

Cwater=molar concentration in water phase

Although the log P value can be generally experimentally determined using n-octanol and water, in the present invention, a partition coefficient (C log P value) determined using a log P value estimation program is used. Specifically, in the present specification, a C log P value determined using “ChemBioDraw ultra ver. 12” is used.

Examples of other polymer compounds include a conjugated polymer and a non-conjugated polymer.

Examples of the surfactant include known surfactants (a cationic surfactant, an anionic surfactant, and the like).

Examples of the antioxidant include IRGANOX 1010 (manufactured by Ciba-Geigy Japan Limited), SUMILIZER GA-80 (manufactured by Sumitomo Chemical Co., Ltd.), SUMILIZER GS (manufactured by Sumitomo Chemical Co., Ltd), SUMILIZER GM (manufactured by Sumitomo Chemical Co., Ltd.), and the like.

Examples of the lightfast stabilizer include TINUVIN 234 (manufactured by BASF SE), CHIMASS ORB 81 (manufactured by BASF SE), CYASORB UV-3853 (manufactured by SUN CHEMICAL COMPANY LTD.), and the like.

Examples of the heat-resistant stabilizer include IRGANOX 1726 (manufactured by BASF SE). Examples of the plasticizer include ADEKASIZER RS (manufactured by ADEKA Corporation) and the like.

A content rate of the components other than the aforementioned dispersion medium is preferably equal to or less than 5% by mass and more preferably 0% to 2% by mass with respect to total solid contents in the composition.

(Preparation of Composition for Forming n-Type Thermoelectric Conversion Layer)

The composition of the present invention can be prepared by mixing together the respective components described above. It is preferable that the composition is prepared by mixing the dispersion medium with CNT, the compound containing a repeating unit represented by Formula (1), and other components if necessary, and dispersing CNT.

The method for preparing the composition is not particularly limited and can be performed using a general mixing device or the like at room temperature and normal pressure. For example, the composition may be prepared by dissolving or dispersing the respective components in a solvent by stirring, shaking, or kneading. In order to accelerate the dissolution or dispersion, an ultrasonic treatment may be performed.

Furthermore, it is possible to improve the dispersibility of carbon nanotubes by means of heating the solvent to a temperature that is equal to or higher than room temperature and equal to or lower than a boiling point in the aforementioned dispersion step, extending the dispersion time, increasing the strength applied at the time of stirring, shaking, or kneading and the intensity of ultrasonic waves, and the like.

<Thermoelectric Conversion Element and Thermoelectric Conversion Layer>

The constitution of the thermoelectric conversion element of the present invention is not particularly limited, as long as the element includes the n-type thermoelectric conversion layer which contains the aforementioned CNT and the compound containing a repeating unit represented by Formula (1) and the p-type thermoelectric conversion layer which is electrically connected to the n-type thermoelectric conversion layer. As will be described later, the n-type thermoelectric conversion layer can be formed using the aforementioned composition.

As long as the n-type thermoelectric conversion layer and the p-type thermoelectric conversion layer are electrically connected to each other, the layers may directly contact each other, or a conductor (for example, an electrode) may be disposed between the layers.

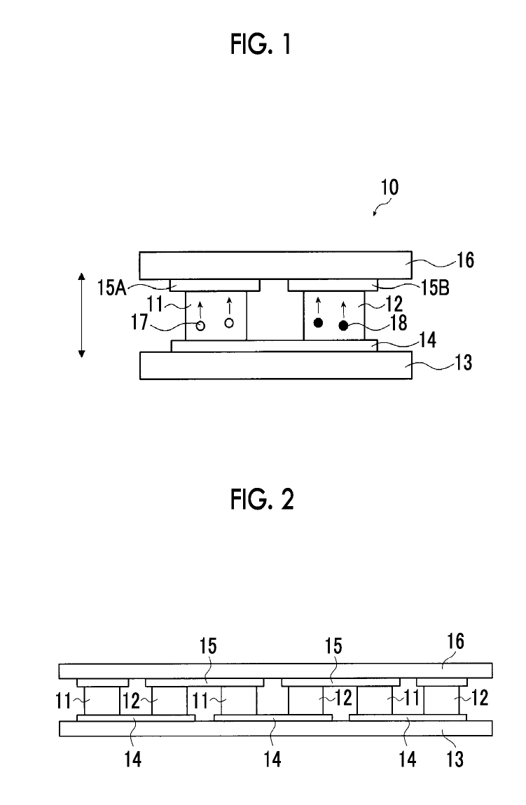

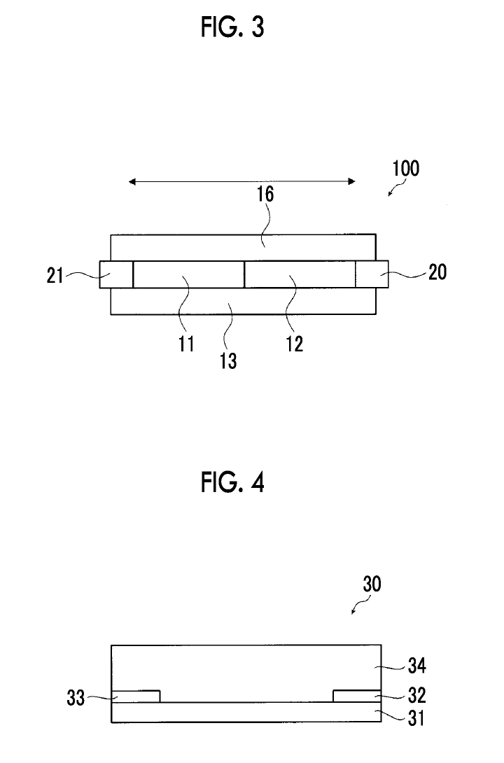

As the structure of the thermoelectric conversion element of the present invention, a structure of an element shown in FIGS. 1 to 3 is exemplified. In FIGS. 1 and 3, the arrow shows a direction of a temperature difference at the time of using the thermoelectric conversion element.

A thermoelectric conversion element 10 shown in FIG. 1 has a p-type thermoelectric conversion layer 11 (p-type thermoelectric conversion portion) and an n-type thermoelectric conversion layer 12 (n-type thermoelectric conversion portion), and these layers are disposed in a line. The n-type thermoelectric conversion layer 12 is a layer formed of the aforementioned composition. The constitutions of the p-type thermoelectric conversion layer 11 and the n-type thermoelectric conversion layer 12 will be specifically described later.

An upper end portion of the p-type thermoelectric conversion layer 11 is electrically and mechanically connected to a first electrode 15A, and an upper end portion of the n-type thermoelectric conversion layer 12 is electrically and mechanically connected to a third electrode 15B. On the outside of the first electrode 15A and the third electrode 15B, an upper substrate 16 is disposed. A lower end portion of each of the p-type thermoelectric conversion layer 11 and the n-type thermoelectric conversion layer 12 is electrically and mechanically connected to a second electrode 14 supported on a lower substrate 13. In this way, the p-type thermoelectric conversion layer 11 and the n-type thermoelectric conversion layer 12 are connected to each other in series through the first electrode 15A, the second electrode 14, and the third electrode 15B. That is, the p-type thermoelectric conversion layer 11 and the n-type thermoelectric conversion layer 12 are electrically connected to each other through the second electrode 14.

The thermoelectric conversion element 10 makes a temperature difference (in the direction of the arrow in FIG. 1) between the upper substrate 16 and the lower substrate 13, and as a result, for example, the upper substrate 16 side becomes a low-temperature portion, and the lower substrate 13 side becomes a high-temperature portion. In a case where such a temperature difference is made, in the p-type thermoelectric conversion layer 11, a hole 17 carrying a positive charge moves to the low-temperature side (upper substrate 16 side), and a potential of the first electrode 15A becomes higher than that of the second electrode 14. In contrast, in the n-type thermoelectric conversion layer 12, an electrode 18 carrying a negative charge moves to the low-temperature portion side (upper substrate 16 side), and a potential of the second electrode 14 becomes higher than that of the third electrode 15B. Consequently, a potential difference occurs between the first electrode 15A and the third electrode 15B, and for example, when a load is connected to the end of the electrode, electric power can be extracted. At this time, the first electrode 15A becomes a positive electrode, and the third electrode 15B becomes a negative electrode.

The thermoelectric conversion element 10 can obtain a higher voltage by, for example, alternately disposing a plurality of p-type thermoelectric conversion layers 11 and a plurality of n-type thermoelectric conversion layers 12 and connecting them to each other in series through the first electrode 15A, the third electrode 15B, and the second electrode 14, as shown in FIG. 2.

In a thermoelectric conversion element 100 shown in FIG. 3, the p-type thermoelectric conversion layer 11 and the n-type thermoelectric conversion layer 12 are disposed such that these are connected to each other in series, a first electrode 20 and a second electrode 21 are disposed on both sides thereof, and the upper substrate 16 and the lower substrate 13 are disposed such that the p-type thermoelectric conversion layer 11 and the n-type thermoelectric conversion layer 12 are interposed between the substrates.

In the thermoelectric conversion element 100, the p-type thermoelectric conversion layer 11 and the n-type thermoelectric conversion layer 12 directly contact each other. In the thermoelectric conversion element 100, by making a temperature difference in the in-plane direction as indicated by the arrow, power can be generated with excellent efficiency.

In FIG. 3, although a single p-type thermoelectric conversion layer and a single n-type thermoelectric conversion layer are connected to each other, a plurality of p-type thermoelectric conversion layers and n-type thermoelectric conversion layers may be alternately disposed.

Hereinafter, each member constituting the thermoelectric conversion element will be specifically described.

(Substrate)

As the substrates of the thermoelectric conversion elements (the upper substrate 16 and the lower substrate 13 in thermoelectric conversion elements 10 and 100), substrates made of transparent ceramics, a metal, a plastic film, and the like can be used. In the thermoelectric conversion element of the present invention, the substrate preferably has flexibility. Specifically, the substrate preferably has such a flexibility that the substrate is found to have an MIT folding endurance of equal to or greater than 10,000 cycles by a measurement method specified by ASTM D2176. As the substrate has such a flexibility, a plastic film is preferable, and specific examples thereof include a polyester film such as polyethylene terephthalate, polyethylene isophthalate, polyethylene naphthalate, polybutylene terephthalate, poly(1,4-cyclohexylenedimethyleneterephthalate), polyethylene-2,6-naphthalenedicarboxylate, and a polyester film of bisphenol A and isophthalic and terephthalic acids, a polycycloolefin film such as a ZEONOR film (trade name, manufactured by ZEON CORPORATION), an ARTON film (trade name, manufactured by JSR Corporation), or SUMILITE FS1700 (trade name, manufactured by Sumitomo Bakelite Co. Ltd.), a polyimide film such as KAPTON (trade name, manufactured by DU PONT-TORAY CO.,LTD.), APICAL (trade name, manufactured by Kaneka Corporation), UPILEX (trade name, manufactured by UBE INDUSTRIES, LTD.), or POMIRAN (trade name, manufactured by Arakawa Chemical Industries, Ltd.), a polycarbonate film such as PUREACE (trade name, manufactured by TEIJIN LIMITED) or ELMEC (trade name, manufactured by Kaneka Corporation), a polyether ether ketone film such as SUMILITE FS1100 (trade name, manufactured by Sumitomo Bakelite Co. Ltd.), a polyphenyl sulfide film such as TORELINA (trade name, manufactured by TORAY INDUSTRIES, INC.), and the like. From the viewpoint of ease of availability, heat stability (preferably equal to or higher than 100° C.), economic feasibility, and effects, commercially available polyethylene terephthalate, polyethylene naphthalate, various polyimide or polycarbonate films, and the like are preferable.

In view of handleability, durability, and the like, a thickness of the substrate is preferably 30 to 3,000 μm, more preferably 50 to 1,000 μm, even more preferably 100 to 1,000 μm, and particularly preferably 200 to 800 μm. If the thickness of the substrate is within the above range, the thermal conductivity is not reduced, and the thermoelectric conversion layer is not easily damaged due to an external shock.

(Electrode)

As electrode materials forming the electrodes in the thermoelectric conversion elements (the second electrode 14, the first electrode 15A, and the third electrode 15B in the thermoelectric conversion element 10 as well as the first electrode 20 and the second electrode 21 in the thermoelectric conversion element 100), it is possible to use a transparent electrode material such as indium tin oxide (ITO) or ZnO, a metal electrode material such as silver, copper, gold, or aluminum, a carbon material such as CNT or graphene, an organic material such as poly(3,4-ethylenedioxythiophene) (PEDOT)/poly(4-styrenesulfonic acid) (PSS), a conductive paste in which conductive fine particles of silver, carbon, and the like are dispersed, a conductive paste containing metal nanowires of silver, copper, or aluminum, and the like. Among these, a metal electrode material such as aluminum, gold, silver, or copper or a conductive paste containing these metals is preferable.

(Thermoelectric Conversion Layers (n-Type Thermoelectric Conversion Layer and p-Type Thermoelectric Conversion Layer))

The n-type thermoelectric conversion layer included in the thermoelectric conversion element of the present invention contains carbon nanotubes and the compound containing a repeating unit represented by Formula (1).

The definitions of the carbon nanotubes and the compound containing a repeating unit represented by Formula (1) are as described above.

A content of the carbon nanotubes in the n-type thermoelectric conversion layer is not particularly limited. In view of further improving the performance of the n-type thermoelectric conversion layer, the content is preferably, with respect to a total mass of the n-type thermoelectric conversion layer, preferably 5% to 80% by mass, more preferably 5% to 70% by mass, and particularly preferably 5% to 50% by mass.

A content of the compound containing a repeating unit represented by Formula (1) in the n-type thermoelectric conversion layer is not particularly limited. In view of further improving the performance of the n-type thermoelectric conversion layer, the content is, with respect to 100 parts by mass of the carbon nanotubes, preferably 10 to 1,000 parts by mass, and more preferably 50 to 400 parts by mass.

The n-type thermoelectric conversion layer may contain materials other than the carbon nanotubes and the compound containing a repeating unit represented by Formula (1), and examples of such materials include optional components (for example, a binder) that the aforementioned composition may contain.

A method for forming the n-type thermoelectric conversion layer is not particularly limited. It is preferable to form the n-type thermoelectric conversion layer by using the aforementioned composition, because then the industrial productivity becomes excellent. More specifically, by coating a substrate with the composition of the present invention and forming a film, the n-type thermoelectric conversion layer can be formed.

The film formation method is not particularly limited, and it is possible to use known coating methods such as a spin coating method, an extrusion die coating method, a blade coating method, a bar coating method, a screen printing method, a stencil printing method, a roll coating method, a curtain coating method, a spray coating method, a dip coating method, and an ink jet method.

If necessary, a drying step is performed after coating. For example, by exposing the film to hot air, a solvent can be volatilized and dried.

As the p-type thermoelectric conversion layer included in the thermoelectric conversion element of the present invention, a known p-type thermoelectric conversion layer can be used. As materials contained in the p-type thermoelectric conversion layer, it is possible to appropriately use known materials (for example, a composite oxide such as NaCo₂O₄ or Ca₃Co₄O₉, a silicide such as MnSi_{1.73}, Fe₁₋ₓMnₓSi₂, Si_{0.8}Ge_{0.2}, or β-FeSi₂, skutterudite such as CoSb₃, FeSb₃, or RFe₃CoSb₁₂ (R represents La, Ce, or Yb), a Te-containing alloy such as BiTeSb, PbTeSb, Bi₂Te₃, or PbTe) and CNT.

In the present invention, from the viewpoint of making a temperature difference, an average thickness of the thermoelectric conversion layers (the n-type thermoelectric conversion layer and the p-type thermoelectric conversion layer) is preferably 0.1 to 1,000 μm, and more preferably 1 to 100 μm.

The average thickness of the thermoelectric conversion layers (the n-type thermoelectric conversion layer and the p-type thermoelectric conversion layer) can be determined by measuring thicknesses of the thermoelectric conversion layers at 10 random points and calculating an arithmetic mean thereof.

In the present invention, if necessary, a washing treatment may be performed on the thermoelectric conversion element having the n-type thermoelectric conversion layer and the p-type thermoelectric conversion layer. The washing treatment is a treatment of bringing a predetermined solvent (water or an organic solvent) into contact with the thermoelectric conversion element.

More specifically, as one of the suitable aspects of a method for manufacturing a thermoelectric conversion element (or a method for washing a thermoelectric conversion element) of the present invention, a method for manufacturing a thermoelectric conversion element (or a method for washing a thermoelectric conversion element) is exemplified which has a step of performing a washing treatment on the element (element having not yet been subjected to a washing treatment) including the n-type thermoelectric conversion layer that contains CNT and the compound containing a repeating unit represented by Formula (1) and the p-type thermoelectric conversion layer that is electrically connected to the n-type thermoelectric conversion layer and contains CNT and a dispersant X (dispersant for CNT), by using a solvent which dissolves the dispersant X without dissolving the compound containing a repeating unit represented by Formula (1).

In the n-type thermoelectric conversion layer containing CNT and the compound containing a repeating unit represented by Formula (1), as described above, presumably, electrons derived from a lone electron pair in a heteroatom in the compound containing a repeating unit represented by Formula (1) may be donated onto CNT, and hence n-type characteristics may be induced. Therefore, it is preferable that the n-type thermoelectric conversion layer contains the compound containing the repeating unit represented by Formula (1). In contrast, in the p-type thermoelectric conversion layer, CNT is doped with a p-type dopant such as oxygen, and as a result, p-type characteristics are induced. Accordingly, if the p-type thermoelectric conversion layer contains an excess of dispersant for CNT, CNT is surrounded with the dispersant. As a result, it is difficult for a p-type dopant such as oxygen to contact CNT, and p-type characteristics deteriorate in some cases.

Therefore, as described above, by performing the washing treatment by using the solvent which dissolves the dispersant X without dissolving the compound containing the repeating unit represented by Formula (1), the dispersant for CNT is removed from the p-type thermoelectric conversion layer, the p-type characteristics are improved, and consequently, the characteristics (particularly, electric conductivity) of the thermoelectric conversion element can be improved.

As the dispersant contained in the p-type thermoelectric conversion layer, a known material can be used as long as it is a dispersant for CNT. Examples thereof include a surfactant such as sodium cholate, sodium deoxycholate, or sodium dodecylbenzenesulfonate, a conjugated polymer, and the like. The surfactant includes an ionic (anionic, cationic, or zwitterionic (amphoteric)) surfactant and a nonionic surfactant, and any of these can be used in the present invention.

The solvent used in the washing treatment is not limited as long as it is a solvent which dissolves the dispersant X without totally or partially dissolving the compound containing a repeating unit represented by Formula (1), and an optimal solvent is appropriately selected according to the type of compound used. Examples of the solvent include an alcohol-based solvent, an aliphatic halogen-based solvent, an aprotic polar solvent, an aromatic solvent, a ketone-based solvent, an ether-based solvent, water, and the like. Among these, an alcohol-based solvent is preferable. Particularly, in a case where a surfactant is used as the dispersant X, an alcohol-based solvent (preferably methanol or ethanol) is preferable.

As the aforementioned “solvent which does not dissolve the compound containing a repeating unit represented by Formula (1)” is preferably a solvent in which a solubility of the compound containing a repeating unit represented by Formula (1) is equal to or lower than 25 g/100 mL at 20° C. The description of “equal to or lower than 25 g/100 mL” shows that a solubility of the compound containing a repeating unit represented by Formula (1) in 100 mL of the solvent is equal to or lower than 25 g.

The aforementioned “solvent which dissolves the dispersant X” is preferably a solvent in which a solubility of the dispersant X is higher than 25 g/100 mL at 20° C.

The washing method is not particularly limited, and known methods can be used. Examples thereof include a method of impregnating the thermoelectric conversion element with a solvent, a method of coating the thermoelectric conversion element with a solvent, and the like.

The conditions of the washing treatment are not particularly limited, and optimal conditions are appropriately selected according to the solvent used. A time of contact between the solvent and the thermoelectric conversion element is preferably about 0.5 to 2 hours.

If necessary, after the washing treatment, a drying treatment may be performed to remove the solvent.

<Article for Thermoelectric Power Generation>

An article for thermoelectric power generation of the present invention is an article for thermoelectric power generation using the thermoelectric conversion element of the present invention.

Specific examples of the article for thermoelectric power generation include a generator such as a hot spring heat power generator, a solar power generator, or a waste heat power generator, a power supply for a wrist watch, a power supply for driving a semiconductor, a power supply for a small sensor, and the like.

That is, the aforementioned thermoelectric conversion element of the present invention can be suitably used for the above purposes.

### EXAMPLES

Hereinafter, the present invention will be more specifically described based on examples, but the present invention is not limited thereto.

### Example A

All the compounds used in examples are shown in Table 1.

In each example, as will be shown below, a commercially available compound or a synthetic compound was used.

Compound 1 of Example 1: poly(ethyleneglycol)octyl ether (n=2 to 9) manufactured by Sigma-Aldrich Co. LLC.

Compound 2 of Example 2: CONION 275-100 manufactured by New Japan Chemical Co., Ltd.

Compound 3 of Example 3 (10, 11): Brij O10 manufactured by Sigma-Aldrich Co. LLC.

Compound 4 of Example 4: EMALEX CS-10 manufactured by Nihon Emulsion Co., Ltd.

Compound 5 of Example 5: INOGEN EN manufactured by DKS Co., Ltd.

Compound 6 of Example 6: synthesized according to the following procedure.

3 g of 1-pyrenebutanoic acid and 7.8 g of polyethylene glycol methyl ether (molecular weight: 750) were dissolved in 50 g of THF, and 2.0 g of 1-(3-dimethylaminopropyl)-3-ethylcarbodiimide hydrochloride was added thereto under ice cooling. Thereafter, the mixture was heated to room temperature and stirred for 3 hours, 200 g of methylene chloride and 200 g of water were then added thereto, and a methylene chloride layer was removed by liquid separation, followed by concentration, thereby obtaining a target substance.

Compound 7 of Example 7: Triton X-405 manufactured by Sigma-Aldrich Co. LLC.

Compound 8 of Example 8: Tween 85 manufactured by Sigma-Aldrich Co. LLC.

Compound 9 of Example 9: Pluronic L-35 (Mn: 1,900, polyethylene glycol (PEG): 50 wt %) manufactured by Sigma-Aldrich Co. LLC.

Compound 12 of Example 12: Brij O20 manufactured by Sigma-Aldrich Co., LLC.

Compound 13 of Example 13: EMULGEN 350 (HLB: 17.8) manufactured by Kao Corporation

Compound 14 of Example 14: Brij S100 manufactured by Sigma-Aldrich Co. LLC.

Compound 15 of Example 15 (16): polyethylene glycol (weight-average molecular weight: 1,400 to 1,600) manufactured by Sigma-Aldrich Co. LLC.

Compound 17 of Example 17: polyvinyl alcohol (weight-average molecular weight: 31,000 to 50,000) manufactured by Sigma-Aldrich Co. LLC.

Compound 18 of Example 18: PVP 40 (weight-average molecular weight: 40,000) manufactured by Sigma-Aldrich Co. LLC.

### Example 1

The compound 1 (112.5 mg) and 37.5 mg of single-layer CNT (manufactured by Meijo Nano Carbon.) were added to 15 ml of water and dispersed for 5 minutes by using a homogenizer. Then, a dispersion treatment (circumferential speed: 40 m/s, stirring for 2.5 minutes) using high shearing force was performed twice by using a FILMIX 40-40 model (manufactured by PRIMIX Corporation), thereby obtaining a dispersion liquid 101 (corresponding to a composition for forming an n-type thermoelectric conversion layer).

As a substrate, a glass substrate having a thickness of 1.1 mm and a size of 40 mm×50 mm was used. The substrate was subjected to ultrasonic cleaning in acetone and then subject to an ultraviolet (UV)-ozone treatment for 10 minutes. Thereafter, a first electrode and a second electrode made of gold having a size of 30 mm×5 mm and a thickness of 10 nm were formed on each of both end portion sides of the substrate.

A frame made of TEFLON (registered trademark) was attached onto the substrate in which electrodes were formed, and the prepared dispersion liquid 101 as a solution was poured into the frame and dried for 1 hour on a hot plate with a temperature of 60° C. After drying, the frame was detached, and a thermoelectric conversion layer having a thickness of about 1.1 μm was formed, thereby preparing a thermoelectric conversion element 30 having the constitution shown in FIG. 4.

In the thermoelectric conversion element 30 shown in FIG. 4, a first electrode 32 and a second electrode 33 are disposed on a substrate 31, and the thermoelectric conversion layer 34 is provided thereon.

The CNT dispersibility in the dispersion liquid and the electric conductivity, thermoelectromotive force, and heat stability of the n-type thermoelectric conversion layer were evaluated by the following methods.

For evaluating the CNT dispersibility, the viscosity of the dispersion liquid was measured. A low viscosity shows that the aggregation of CNT does not occur, and the CNT dispersibility is excellent.

[Measurement of Viscosity]

By using a rheometer (manufactured by THERMO ELECTRON Co., Ltd., HAAKE RheoStress 600), the viscosity of the dispersion liquid was measured at a shearing rate of 20/s and a temperature of 25° C. and evaluated according to the following standards.

“AAA”: the viscosity was less than 1 Pa·s.

“AA”: the viscosity was equal to or higher than 1 Pa·s and less than 2 Pa·s.

“A: the viscosity was equal to or higher than 2 Pa·s and less than 3 Pa·s.

“B”: the viscosity was equal to or higher than 3 Pa·s and less than 5 Pa·s.

“C”: the viscosity was higher than 5 Pa·s.

[Thermoelectromotive Force and Electric Conductivity]

The first electrode of the thermoelectric conversion element was installed on a hot plate kept at a constant temperature, and the second electrode was installed on a Peltier element for temperature control. That is, the hot plate was installed below the substrate 31 in which the first electrode 32 in FIG. 4 was positioned, and the Peltier element was disposed below the substrate 31 in which the second electrode 33 was positioned.

In a state where hot plate was being kept at a constant temperature (100° C.), a temperature difference (within a range of higher than 0 K and equal to or lower than 4 K) was made between the two electrodes by lowering the temperature of the Peltier element.

At this time, a thermoelectromotive force (μV) that occurred between the two electrodes was divided by a specific temperature difference (K) that occurred between the two electrodes, and in this way, a thermoelectromotive force S (μV/K) per unit temperature difference was calculated. Furthermore, by measuring the electric current that occurred between the two electrodes, an electric conductivity (S/cm) was calculated. The results are summarized in Table 1.

[Heat Stability]

The thermoelectric conversion element was allowed to stand on a hot plate and subjected to a heating treatment for 4 hours at 60° C. Then, by using the thermoelectric conversion element having undergone the heating treatment, the aforementioned [Thermoelectromotive force] was evaluated, and a rate of change (%) of the thermoelectromotive force before and after heating was calculated by [{(|thermoelectromotive force before heating treatment|−|thermoelectromotive force after heating treatment|)/|thermoelectromotive force before heating treatment|}×100].

### Examples 2 to 18 and Comparative Examples 1 and 2

Thermoelectric conversion elements were prepared according to the same procedure as in Example 1, except that either or both of the compound used and the type of solvent were changed as shown in Table 1 which will be shown below. By using the prepared dispersion liquids and thermoelectric conversion elements, various evaluations were performed. The results are summarized in Table 1.

In Example 16, instead of the compound 1 (112.5 mg), sodium 1-octadecanesulfonate (C₁₈H₃₇SO₃Na) (112.5 mg) and the compound 15 (HO—(CH₂CH₂O)₃₄—H) (112.5 mg) were used in combination.

In Comparative Example 1, dodecyltrimethylammonium bromide (manufactured by TOKYO CHEMICAL INDUSTRY CO., LTD.) was used.

In Comparative Example 2, instead of the compound 1 (112.5 mg), polystyrene (112.5 mg) and triphenylphosphine (112. 5 mg) were used in combination.

In Table 1, “≦3” in the column of “Heat stability” means “equal to or less than 3%”.

Furthermore, PGMEA means propylene glycol monomethyl ether acetate.

TABLE 1

| | Type of | | | | Evaluation | | | |
|---|---|---|---|---|---|---|---|---|
| | thermo- | | | | | Electric | Thermo | |
| | electric | Composition | | | | conduc- | electro- | Heat |
| | conversion | | | Solvent | | tivity | motive force | stability |
| | element | Type | Polymer | (ClogP) | Viscosity | (S/cm) | (μV/K) | (%) |
| Example 1 | 101 | 1 | 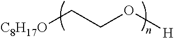 | Water (−1.38) | A | 300 | −35 | ≦3 |
| Example 2 | 102 | 2 | 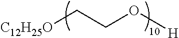 | Water (−1.38) | A | 300 | −40 | ≦3 |
| Example 3 | 103 | 3 | 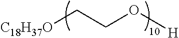 | Water (−1.38) | A | 300 | −45 | ≦3 |
| Example 4 | 104 | 4 | 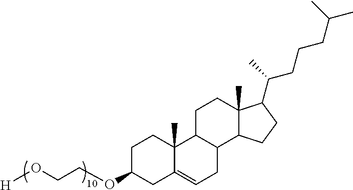 | Water (−1.38) | A | 300 | −45 | ≦3 |
| Example 5 | 105 | 5 | 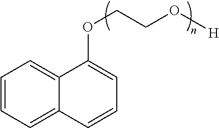 | Water (−1.38) | A | 300 | −50 | ≦3 |
| Example 6 | 106 | 6 | 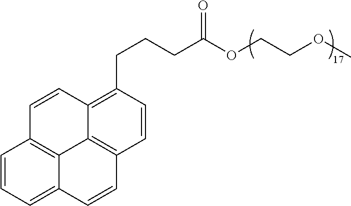 | Water (−1.38) | A | 350 | −50 | ≦3 |
| Example 7 | 107 | 7 | 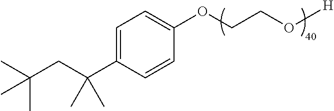 | Water (−1.38) | A | 300 | −40 | ≦3 |
| Example 8 | 108 | 8 | 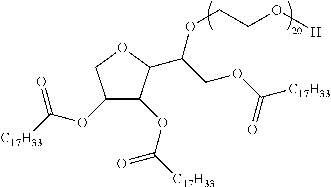 | Water (−1.38) | A | 300 | −50 | ≦3 |
| Example 9 | 109 | 9 | 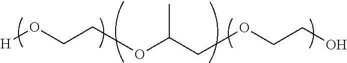 | Water (−1.38) | A | 300 | −35 | ≦3 |
| Example 10 | 110 | 3 | 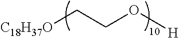 | Methyl carbitol (−0.74) | A | 300 | −35 | ≦3 |
| Example 11 | 111 | 3 | 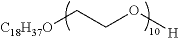 | PGMEA (0.60) | A | 300 | −30 | ≦3 |
| Example 12 | 112 | 12 | 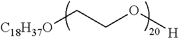 | Water (−1.38) | AA | 350 | −55 | ≦3 |
| Example 13 | 113 | 13 | 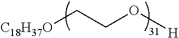 | Water (−1.38) | AAA | 400 | −60 | ≦3 |
| Example 14 | 114 | 14 | 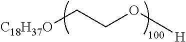 | Water (−1.38) | A | 350 | −55 | ≦3 |
| Example 15 | 115 | 15 | 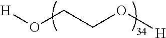 | Water (−1.38) | A | 300 | −30 | ≦3 |
| Example 16 | 116 | 15 | 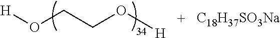 | Water (−1.38) | A | 300 | −30 | ≦3 |
| Example 17 | 117 | 17 | 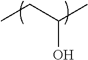 | Water (−1.38) | A | 350 | −30 | ≦3 |
| Example 18 | 118 | 18 | 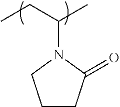 | Water (−1.38) | A | 350 | −30 | ≦3 |
| Compara- | 201 | — | Dodecyltrimethylammonium bromide | Water | C | 300 | −5 | 30 |
| tive | | | | (−1.38) | | | | |
| Example | | | | | | | | |
| 1 | | | | | | | | |
| Compara- | 202 | — | Polystyrene + triphenylphosphine | Methyl | C | 200 | −30 | 40 |
| tive | | | | carbitol | | | | |
| Example | | | | (−0.74) | | | | |
| 2 | | | | | | | | |

As shown in Table 1, it was confirmed that the n-type thermoelectric conversion layer of the present invention has a negative thermoelectromotive force, and hence the n-type thermoelectric conversion layer functions as an n-type semiconductor and has excellent electric conductivity, thermoelectromotive force, and heat stability. Furthermore, the CNT dispersibility in the obtained composition for forming an n-type thermoelectric conversion layer was excellent.

Through the comparison of Examples 1 to 3 and 12 to 14, it was confirmed that, in a case where n is 10 to 120, better effects are obtained.

Through the comparison of Examples 1 to 7, it was confirmed that, in a case where the compound has a monovalent hydrocarbon group having 10 or more carbon atoms on at least one of the main chain terminals thereof, better effects are obtained.

Through the comparison of Examples 3, 10, and 11, it was confirmed that, in a case where water or an alcohol-based solvent having a C log P value of equal to or less than 3.0 is used, better effects are obtained.

In contrast, in Comparative Examples 1 and 2 in which the predetermined compound was not used, desired effects were not obtained.

### Example B

### Example 21

(Composition for Forming p-Type Thermoelectric Conversion Layer 1)

Sodium cholate (112.5 mg) and single-layer CNT (manufactured by Meijo Nano Carbon.) (37.5 mg) were added to 15 ml of water and dispersed for 5 minutes by using a homogenizer. Then, a dispersion treatment (circumferential speed: 40 m/s, stirring for 2.5 minutes) using a high shearing force was performed twice by using a FILMIX 40-40 model (manufactured by PRIMIX Corporation), thereby obtaining a dispersion liquid (composition for forming a p-type thermoelectric conversion layer 1).

(Preparation of p-Type Thermoelectric Conversion Element)

By using the composition for forming a p-type thermoelectric conversion layer 1 as a dispersion liquid, a p-type thermoelectric conversion element 1 was prepared by the same step as used for preparing the thermoelectric conversion element 30.

(Preparation of p-n Junction Thermoelectric Conversion Element)

The electrodes in the thermoelectric conversion element 30 were connected to the electrodes in the p-type thermoelectric conversion element 1 through conductive wire, thereby preparing a p-n junction thermoelectric conversion element (thermoelectric conversion element in which the p-type thermoelectric conversion layer and the n-type thermoelectric conversion layer are electrically connected to each other). The obtained thermoelectric conversion element was evaluated in the same manner as described above. As a result, it was confirmed that an absolute value of the thermoelectromotive force thereof is 65 μV/K.

### Examples 22 to 38 and Comparative Examples 11 to 21

p-n junction thermoelectric conversion elements (thermoelectric conversion elements in which the p-type thermoelectric conversion layer and the n-type thermoelectric conversion layer are electrically connected to each other) were prepared according to the same procedure as in Example 21, except that the thermoelectric conversion elements shown in Table 2 were used instead of the thermoelectric conversion element 101 (n-type thermoelectric conversion element). The thermoelectromotive force and the heat stability of the elements were measured. The results are summarized in Table 2.

TABLE 2

| | Type of n-type | | Heat |
|---|---|---|---|
| | thermoelectric | Thermoelectromotive | stability |
| | conversion element | force (μV/K) | (%) |
| Example 21 | 101 | 65 | ≦3 |
| Example 22 | 102 | 70 | ≦3 |
| Example 23 | 103 | 75 | ≦3 |
| Example 24 | 104 | 75 | ≦3 |
| Example 25 | 105 | 80 | ≦3 |
| Example 26 | 106 | 80 | ≦3 |
| Example 27 | 107 | 70 | ≦3 |
| Example 28 | 108 | 75 | ≦3 |
| Example 29 | 109 | 65 | ≦3 |
| Example 30 | 110 | 65 | ≦3 |
| Example 31 | 111 | 60 | ≦3 |
| Example 32 | 112 | 85 | ≦3 |
| Example 33 | 113 | 90 | ≦3 |
| Example 34 | 114 | 85 | ≦3 |
| Example 35 | 115 | 60 | ≦3 |
| Example 36 | 116 | 60 | ≦3 |
| Example 37 | 117 | 60 | ≦3 |
| Example 38 | 118 | 60 | ≦3 |
| Comparative | 201 | 35 | 20 |
| Example 11 | | | |
| Comparative | 202 | 60 | 30 |
| Example 21 | | | |

As shown in Table 2, the p-n junction thermoelectric conversion element of the present invention exhibited excellent thermoelectric conversion characteristics.

In contrast, in the thermoelectric conversion elements of Comparative Examples 11 and 21 not having the predetermined n-type thermoelectric conversion layer, desired effects (thermoelectromotive force and heat stability) were not obtained.

### Example C

### Synthesis Example 1

### Synthesis of Polymer 1

1 g of dodecyl methacrylate, 4 g of BLEMMER PME-4000, and 8 g of dimethylacetamide were put into a three-neck flask having a volume of 300 mL and heated to 80° C. Then, 0.0127 g of a polymerization initiator V-601 (manufactured by Wako Pure Chemical Industries, Ltd.) was added thereto, and the reactants were reacted for 2 hours. Furthermore, the step of adding 0.0127 g of V-601 (manufactured by Wako Pure Chemical Industries, Ltd.) and reacting the reactants for 2 hours was repeated twice. The obtained reaction solution was reprecipitated, thereby obtaining 3 g of a target polymer 1.

In the following formulae, n is 90. In addition, in the following formulae, a molar ratio of repeating unit on left side:repeating unit on right side was 80:20.

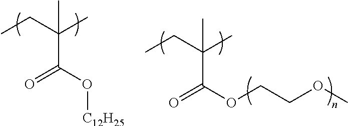

### Synthesis Example 2

### Synthesis of Polymer 2

1 g of benzylmethacrylate, 4 g of BLEMMER PME-4000, and 8 g of dimethylacetamide were put into a three-neck flask having a volume of 300 mL and heated to 80° C. Then, 0.0127 g of a polymerization initiator V-601 (manufactured by Wako Pure Chemical Industries, Ltd.) was added thereto, and the reactants were reacted for 2 hours. Furthermore, the step of adding 0.0127 g of V-601 (manufactured by Wako Pure Chemical Industries, Ltd.) and reacting the reactants for 2 hours was repeated twice. The obtained reaction solution was reprecipitated, thereby obtaining 3 g of a target polymer 2.

In the following formulae, n is 90. In addition, in the following formulae, a molar ratio of repeating unit on left side:repeating unit on right side was 85:15.

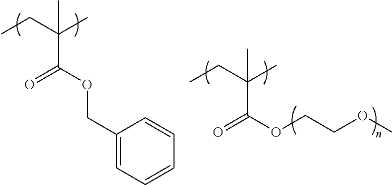

### Synthesis Example 3

### Synthesis of Polymer 3

5 g of 1-bromoacetyl pyrene, 2.7 g of dimethylaminopropyl acrylamide, and 50 mL of tetrahydrofuran were put into a three-neck flask having a volume of 300 mL and reacted for 3 hours at room temperature. After the reaction, the precipitate of the reaction solution was filtered, thereby obtaining 6 g of a target monomer 1.

1 g of the obtained monomer 1, 4 g of BLEMMER PME-4000, and 8 g of dimethylacetamide were put into a three-neck flask having a volume of 300 mL and heated to 80° C. Then, 0.0127 g of a polymerization initiator V-601 (manufactured by Wako Pure Chemical Industries, Ltd.) was added thereto, and the reactants were reacted for 2 hours. Furthermore, the step of adding 0.0127 g of V-601 (manufactured by Wako Pure Chemical Industries, Ltd.) and reacting the reactants for 2 hours was repeated twice. The obtained reaction solution was reprecipitated, thereby obtaining 3 g of a target polymer 3.

In the following formulae, n is 90. In addition, in the following formulae, a molar ratio of repeating unit on left side:repeating unit on right side was 72:28.

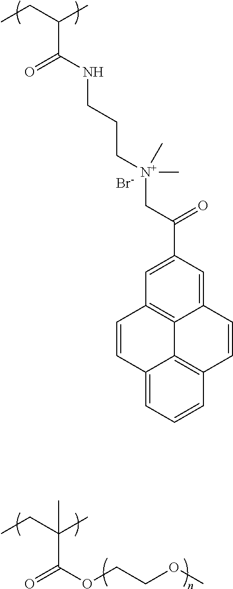

### Examples 40 to 46

Thermoelectric conversion elements were prepared according to the same procedure as in Example 1, except that the type of the compound 1 of <Example 1> was changed as shown in Table 3, and the type of solvent was changed as shown in Table 3. By using the prepared dispersion liquids and thermoelectric conversion elements, various evaluations were performed. The results are summarized in Table 3.

In Example 44, the polymer 1 and sodium cholate were used together. An amount of the polymer 1 used was 112.5 mg, and an amount of the sodium cholate used was 112.5 mg.

In Example 45, the polymer 1 and sodium deoxycholate were used together. An amount of the polymer 1 used was 112.5 mg, and an amount of the sodium deoxycholate used was 112.5 mg.

In Example 46, the polymer 1 and sodium dodecylbenzenesulfonate were used together. An amount of the polymer 1 used was 112.5 mg, and an amount of the sodium dodecylbenzenesulfonate used was 112. 5 mg.

TABLE 3

| | Type of | | | | Evaluation | | | |
|---|---|---|---|---|---|---|---|---|
| | thermoelectric | Composition | | | | Electric | Thermoelectromotive | Heat |
| | conversion | | | Solvent | | conductivity | force | stability |
| | element | Type | Compound | (ClogP) | Viscosity | (S/cm) | (μV/K) | (%) |
| Example | 120 | 20 | Polymer 1 | Methyl | A | 300 | −37 | ≦3 |
| 40 | | | | carbitol | | | | |
| | | | | (−0.74) | | | | |
| Example | 121 | 21 | Polymer 2 | Methyl | A | 300 | −38 | ≦3 |
| 41 | | | | carbitol | | | | |
| | | | | (−0.74) | | | | |
| Example | 122 | 22 | Polymer 3 | Methyl | A | 300 | −40 | ≦3 |
| 42 | | | | carbitol | | | | |
| | | | | (−0.74) | | | | |
| Example | 123 | 23 | Polymer 3 | Water | AA | 310 | −40 | ≦3 |
| 43 | | | | (−1.38) | | | | |
| Example | 124 | 24 | Polymer 3 + sodium | Water | AAA | 320 | −41 | ≦3 |
| 44 | | | cholate | (−1.38) | | | | |
| Example | 125 | 25 | Polymer 3 + sodium | Water | AAA | 320 | −42 | ≦3 |
| 45 | | | deoxycholate | (−1.38) | | | | |
| Example | 126 | 26 | Polymer 3 + sodium | Water | AAA | 320 | −43 | ≦3 |
| 46 | | | dodecylbenzenesulfonale | (−1.38) | | | | |

As shown in Table 3, it was confirmed that the n-type thermoelectric conversion layer of the present invention has a negative thermoelectromotive force, and hence the n-type thermoelectric conversion layer functions as an n-type semiconductor and has excellent electric conductivity, thermoelectromotive force, and heat stability. Furthermore, the CNT dispersibility in the obtained composition for forming an n-type thermoelectric conversion layer was excellent.

### Example D

### Synthesis Example 4

### Synthesis of Polymer 4

100 g of methyl methacrylate and 0.35 g of 3-mercaptopropionate were put into a three-neck flask having a volume of 250 mL and heated to 80° C. After heating, 17 mg of azobisisobutyronitrile (AIBN, manufactured by Wako Pure Chemical Industries, Ltd.) was added thereto, and the reactants were reacted for 40 minutes. Then, the step of adding 17 mg of AIBN (manufactured by Wako Pure Chemical Industries, Ltd.) and reacting the reactants for 40 minutes was repeated twice. Thereafter, by adding 10 g of tetrahydrofuran, the reaction was finished. The reaction solution was reprecipitated, thereby obtaining 60 g of an intermediate A.

15 g of the obtained intermediate A, 30 g of xylene, 0.28 g of glycidyl methacrylate, 0.01 g of hydroquinone, and 0.01 g of dimethyl lauryl amine were put into a three-neck flask having a volume of 250 mL and reacted for 5 hours under reflux conditions. Then, the reaction solution was reprecipitated, thereby obtaining 10 g of a macromonomer of polymethyl methacrylate (PMMA).

5 g of 1-bromoacetylpyrene, 2.7 g of dimethylaminopropyl acrylamide, and 50 mL of tetrahydrofuran were put into a three-neck flask having a volume of 300 mL and reacted for 3 hours at room temperature. After the reaction, the precipitate of the reaction solution was filtered, thereby obtaining 6 g of a target monomer 2.

1 g of the obtained monomer 2, 4 g of the macromonomer of PMMA synthesized as above, and 8 g of dimethylacetamide were put into a three-neck flask having a volume of 300 mL and heated to 80° C. Then, 0.0127 g of a polymerization initiator V-601 (manufactured by Wako Pure Chemical Industries, Ltd.) was added thereto, and the reactants were reacted for 2 hours. Furthermore, the step of adding 0.0127 g of V-601 (manufactured by Wako Pure Chemical Industries, Ltd.) and reacting the reactants for 2 hours was repeated twice. The obtained reaction solution was reprecipitated, thereby obtaining 3 g of a target polymer 4 (weight-average molecular weight=32,000).

(Composition for Forming p-Type Thermoelectric Conversion Layer 2)

112. 5 mg of the polymer 4 and 37.5 mg of single-layer CNT (manufactured by Meijo Nano Carbon.) were added to 15 ml of dimethyl carbitol and dispersed for 5 minutes by using a homogenizer. Then, a dispersion treatment (circumferential speed: 40 m/s, stirring for 2.5 minutes) using a high shearing force was performed twice by using a FILMIX 40-40 model (manufactured by PRIMIX Corporation), thereby preparing a dispersion liquid (composition for forming a p-type thermoelectric conversion layer 2).

(Preparation of p-Type Thermoelectric Conversion Element 2)

By using the composition for forming a p-type thermoelectric conversion layer 2 as a dispersion liquid, a p-type thermoelectric conversion element 2 was prepared by the same step as used for preparing the thermoelectric conversion element 30.

(Composition for Forming p-Type Thermoelectric Conversion Layer 3)

112.5 mg of sodium deoxycholate and 37.5 mg of single-layer CNT (manufactured by Meijo Nano Carbon.) were added to 15 ml of water and dispersed for 5 minutes by using a homogenizer. Then, a dispersion treatment (circumferential speed: 40 m/s, stirring for 2.5 minutes) using a high shearing force was performed twice by using a FILMIX 40-40 model (manufactured by PRIMIX Corporation), thereby obtaining a dispersion liquid (composition for forming a p-type thermoelectric conversion layer 3).

(Preparation of p-Type Thermoelectric Conversion Element 3)

By using the composition for forming a p-type thermoelectric conversion layer 3 as a dispersion liquid, a p-type thermoelectric conversion element 3 was prepared by the same step as used for preparing the thermoelectric conversion element 30.

### Examples 50 to 55

(Preparation of p-n Junction Thermoelectric Conversion Element)

The electrodes in the n-type thermoelectric conversion element shown in Table 3 were connected to the electrodes in the p-type thermoelectric conversion element 2 or 3 through conductive wire, thereby preparing p-n junction thermoelectric conversion elements (thermoelectric conversion elements in which the n-type thermoelectric conversion layer and the p-type thermoelectric conversion layer are electrically connected to each other). The electric conductivity, thermoelectromotive force, and heat stability of the elements were measured. The results are summarized in Table 4.

The column of “Presence or absence of washing step” listed in Table 4 shows that whether or not the following washing step was performed on the thermoelectric conversion element.

Washing step: after being formed, the thermoelectric conversion element was impregnated for 1 hour with 100 mL of ethanol and then dried for 2 hours at 120° C. on a hot plate.

TABLE 4

| | | Type of n-type | Presence or | | | |
|---|---|---|---|---|---|---|
| | Type of p-type | thermoelectric | absence of | Electric | Thermoelectromotive | Heat |
| | thermoelectric | conversion | washing | conductivity | force | stability |
| | conversion element | element | step | (S/cm) | (μv/K) | (%) |
| Example 50 | p-type thermoelectric | 123 | Absent | 300 | 72 | ≦3 |
| | conversion element 2 | | | | | |
| Example 51 | p-type thermoelectric | 123 | Present | 350 | 72 | ≦3 |
| | conversion element 2 | | | | | |
| Example 52 | p-type thermoelectric | 123 | Absent | 320 | 75 | ≦3 |
| | conversion element 3 | | | | | |
| Example 53 | p-type thermoelectric | 123 | Present | 450 | 75 | ≦3 |
| | conversion element 3 | | | | | |
| Example 54 | p-type thermoelectric | 125 | Absent | 330 | 82 | ≦3 |
| | conversion element 3 | | | | | |
| Example 55 | p-type thermoelectric | 125 | Present | 500 | 82 | ≦3 |
| | conversion element 3 | | | | | |

As shown in Table 4, the p-n junction thermoelectric conversion element of the present invention exhibited excellent thermoelectric conversion characteristics. Particularly, in a case where the washing step was performed, the electric conductivity was further improved.

### EXPLANATION OF REFERENCES

10, 30, 100: thermoelectric conversion element

11: p-type thermoelectric conversion layer

12: n-type thermoelectric conversion layer

13: lower substrate

14, 21, 33: second electrode

15A, 20, 32: first electrode

15B: third electrode

16: upper substrate

31: substrate

What is claimed is:

1. A thermoelectric conversion element comprising:
an n-type thermoelectric conversion layer; and
a p-type thermoelectric conversion layer electrically connected to the n-type thermoelectric conversion layer,
wherein the n-type thermoelectric conversion layer contains carbon nanotubes and a compound containing a repeating unit represented by Formula (1),
L₁-Xₙ Formula (1)
in Formula (1), L₁ represents a divalent hydrocarbon group, n represents an integer of equal to or greater than 2, and X represents —O—, —CH(OH)—, —S—, —OC(═O)O—, —C(═O)—, —OC(═O)—, or a divalent group containing an amide group.

2. The thermoelectric conversion element according to claim 1,
wherein the compound contains a compound represented by Formula (3),
R₁-L₃L₁-XₙR₂ Formula (3)
in Formula (3), R₁ represents a monovalent hydrocarbon group having 10 or more carbon atoms, R₂ represents a hydrogen atom or a monovalent organic group, L₁ represents a divalent hydrocarbon group, L₃ represents a single bond or a divalent linking group, X represents —O—, —CH(OH)—, —S—, —OC(═O)O—, —C(═O)—, —OC(═O)—, or a divalent group containing an amide group, and n represents an integer of equal to or greater than 2.

3. The thermoelectric conversion element according to claim 1,
wherein a content of the compound is 50 to 400 parts by mass with respect to 100 parts by mass of the carbon nanotubes.

4. The thermoelectric conversion element according to claim 1,
wherein L₁ is an ethylene group or a propylene group, and
X is —O—.

5. The thermoelectric conversion element according to claim 2,
wherein R₂ is a hydrogen atom, and
X is —O—.

6. The thermoelectric conversion element according to claim 1,
wherein an average thickness of the n-type thermoelectric conversion layer is 1 to 100 μm.

7. The thermoelectric conversion element according to claim 1,
wherein the compound is a compound containing a repeating unit represented by Formula (1A) and a repeating unit represented by Formula (1B), 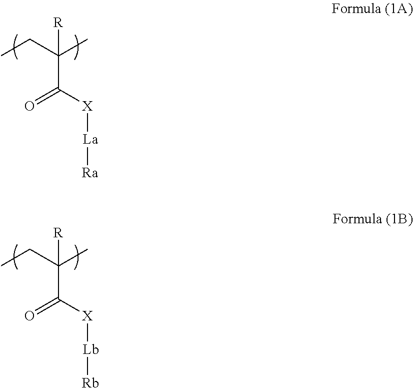
in Formula (1A), Ra represents an aromatic group, an alicyclic group, an alkyl group, a hydroxyl group, a thiol group, an amino group, an ammonium group, or a carboxy group, La represents a single bond or a divalent linking group, R represents a hydrogen atom or an alkyl group having 1 to 4 carbon atoms, and X represents an oxygen atom or —NH—,
in Formula (1B), Rb represents a group containing a repeating unit represented by Formula (1), Lb represents a single bond or a divalent linking group, R represents a hydrogen atom or an alkyl group having 1 to 4 carbon atoms, and X represents an oxygen atom or —NH—,
L₁-Xₙ Formula (1)
in Formula (1), L₁ represents a divalent hydrocarbon group, n represents an integer of equal to or greater than 2, and X represents —O—, —CH(OH)—, —S—, —OC(═O)O—, —C(═O)—, —OC(═O)—, or a divalent group containing an amide group.

8. An n-type thermoelectric conversion layer comprising:
carbon nanotubes; and
a compound containing a repeating unit represented by Formula (1),
L₁-Xₙ Formula (1)
in Formula (1), L₁ represents a divalent hydrocarbon group, n represents an integer of equal to or greater than 2, and X represents —O—, —CH(OH)—, —S—, —OC(═O)O—, —C(═O)—, —OC(═O)—, or a divalent group containing an amide group.

9. The n-type thermoelectric conversion layer according to claim 8,
wherein the compound contains a compound represented by Formula (3),
R₁-L₃L₁-XₙR₂ Formula (3)
in Formula (3), R₁ represents a monovalent hydrocarbon group having 10 or more carbon atoms, R₂ represents a hydrogen atom or a monovalent organic group, L₁ represents a divalent hydrocarbon group, L₃ represents a single bond or a divalent linking group, X represents —O—, —CH(OH)—, —S—, —OC(═O)O—, —C(═O)—, —OC(═O)—, or a divalent group containing an amide group, and n represents an integer of equal to or greater than 2.

10. The n-type thermoelectric conversion layer according to claim 8,
wherein a content of the compound is 50 to 400 parts by mass with respect to 100 parts by mass of the carbon nanotubes.

11. The n-type thermoelectric conversion layer according to claim 8,
wherein L₁ is an ethylene group or a propylene group, and
X is —O—.

12. The n-type thermoelectric conversion layer according to claim 9,
wherein R₂ is a hydrogen atom, and
X is —O—.

13. The n-type thermoelectric conversion layer according to claim 8,
wherein the compound is a compound containing a repeating unit represented by Formula (1A) and a repeating unit represented by Formula (1B), 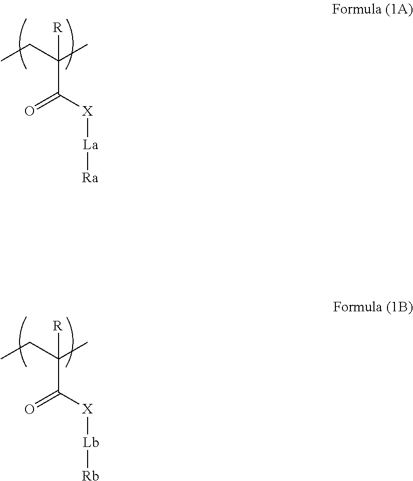
in Formula (1A), Ra represents an aromatic group, an alicyclic group, an alkyl group, a hydroxyl group, a thiol group, an amino group, an ammonium group, or a carboxy group, La represents a single bond or a divalent linking group, R represents a hydrogen atom or an alkyl group having 1 to 4 carbon atoms, and X represents an oxygen atom or —NH—,
in Formula (1B), Rb represents a group containing a repeating unit represented by Formula (1), Lb represents a single bond or a divalent linking group, represents a hydrogen atom or an alkyl group having 1 to 4 carbon atoms, and X represents an oxygen atom or —NH—,
L₁-Xₙ Formula (1)
in Formula (1), L₁ represents a divalent hydrocarbon group, n represents an integer of equal to or greater than 2, and X represents —O—, —CH(OH)—, —S—, —OC(═O)O—, —C(═O)—, —OC(═O)—, or a divalent group containing an amide group.

14. A composition for forming an n-type thermoelectric conversion layer, comprising:
carbon nanotubes; and
a compound containing a repeating unit represented by Formula (1),
wherein the composition further comprises
water, or
an alcohol-based solvent having a C log P value of equal to or less than 3.0,
L₁-Xₙ Formula (1)
in Formula (1), L₁ represents a divalent hydrocarbon group, n represents an integer of equal to or greater than 2, and X represents —O—, —CH(OH)—, —S—, —OC(═O)O—, —C(═O)—, —OC(═O)—, or a divalent group containing an amide group.

15. The thermoelectric conversion element according to claim 2,
wherein a content of the compound is 50 to 400 parts by mass with respect to 100 parts by mass of the carbon nanotubes.

16. The thermoelectric conversion element according to claim 2,
wherein L₁ is an ethylene group or a propylene group, and
X is —O—.

17. The thermoelectric conversion element according to claim 3,
wherein L₁ is an ethylene group or a propylene group, and
X is —O—.

18. The thermoelectric conversion element according to claim 2,
wherein an average thickness of the n-type thermoelectric conversion layer is 1 to 100 μm.

19. The thermoelectric conversion element according to claim 3,
wherein an average thickness of the n-type thermoelectric conversion layer is 1 to 100 μm.

20. The thermoelectric conversion element according to claim 4,
wherein an average thickness of the n-type thermoelectric conversion layer is 1 to 100 μm.
